(19) United States
(12) Patent Application Publication
(10) Pub. No.: US 2014/0009446 A1
(43) Pub. Date: Jan. 9, 2014

(54) DISPLAY PANEL, ORGANIC LIGHT EMITTING DISPLAY DEVICE HAVING THE SAME, AND METHOD OF MANUFACTURING A DISPLAY PANEL

(71) Applicant: SAMSUNG DISPLAY CO., LTD., Yongin-city (KR)

(72) Inventors: Hae-Yeon Lee, Yongin-city (KR); Young-In Hwang, Yongin-city (KR)

(73) Assignee: Samsung Display Co., Ltd., Yongin-city (KR)

(21) Appl. No.: 13/892,015

(22) Filed: May 10, 2013

(30) Foreign Application Priority Data
Jul. 3, 2012 (KR) 10-2012-0072116

(51) Int. Cl. G09G 3/32

(52) U.S. Cl. CPC G09G 3/3208
USPC 345/204; 345/82

(57) ABSTRACT

A method of manufacturing a display panel of an organic light emitting display device, where the display panel has a plurality of pixels, is disclosed. By the method, a plurality of pixel groups is determined by grouping the pixels of the display panel, respective resonance-efficiencies of the pixel groups are calculated based on respective distances between a power unit and the pixel groups, and the pixels of the display panel are formed according to the respective resonance-efficiencies of the pixel groups.

### CROSS-REFERENCE TO RELATED APPLICATIONS

This application claims priority under 35 USC §119 to Korean Patent Applications No. 10-2012-0072116, filed on Jul. 3, 2012 in the Korean Intellectual Property Office (KIPO), the contents of which are incorporated herein in its entirety by reference.

### BACKGROUND

1. Field

The disclosed technology generally relates to an organic light emitting display device. More particularly, a display panel, an organic light emitting display device having the display panel, and a method of manufacturing the display panel consider resonance efficiencies of pixels that are different distances from the power source and compensating accordingly.

2. Description of the Related Technology

Generally, since an organic light emitting diode (OLED) device is self-emitting, the device has no need for a separate light source such as a backlight. Thus, OLED displays can be manufactured thinner and lighter than those that use liquid crystal display (LCD) technology. In addition, OLED displays have various advantages including those related to power consumption, luminance, speed of response, etc. compared to LCD devices. For this reason, more and more flat panel display devices are using OLED technology.

Typically, each pixel is coupled between a high power voltage ELVDD and a low power voltage ELVSS. Here, each pixel emits light based on a current flowing through the OLED (i.e., referred to as an emission current), where the emission current is controlled by a driving transistor. Thus, when a ground voltage GND is used as the low power voltage ELVSS, luminance of each pixel (i.e., the OLED) increases as the high power voltage ELVDD increases. In other words, the higher the high power voltage ELVDD is, the greater the luminance of each pixel.

The current flowing through the OLED needs to be controlled by a data signal applied to each pixel by the high power voltage ELVDD or the low power voltage ELVSS sources. Thus, the high power voltage ELVDD is required to be substantially the same (i.e., uniform) for all pixels. However, since OLED devices are being manufactured in larger sizes (i.e., display panels are getting wider), the high power voltage ELVDD changes according to a location of respective pixels on the display panel.

Specifically, the high power voltage ELVDD is transferred from a power unit (e.g., a power supplying device) to pixels via power-lines. Here, a voltage drop (e.g., IR-DROP) occurs because the high power voltage ELVDD is transferred via power-lines which span the width of the display. Thus, pixels that are far from the power unit will receive the high power voltage ELVDD signal having a relatively low voltage level, whereas pixels that are near to the power unit will receive the high power voltage ELVDD signal having a relatively high voltage level. As a result, even when the same data signal is applied to each pixel, luminance of a display region (i.e., one group of pixels) that is far from the power unit may be lower than luminance of a display region (i.e., another group of pixels) that is near to the power unit.

### SUMMARY OF CERTAIN INVENTIVE ASPECTS

In some embodiments of the disclosed technology a display panel is capable of preventing luminance non-uniformity that is caused by a voltage drop (e.g., IR-DROP) of a high power voltage, the voltage drop occurring when the high power voltage is transferred via power-lines over a distance.

Some embodiments are an organic light emitting display device having the display panel.

Some embodiments are a method of manufacturing the display panel.

According to some example embodiments, a method of manufacturing a display panel of an organic light emitting diode (OLED) display, wherein the display panel has a plurality of pixels, of the method comprising: determining a plurality of pixel groups by grouping the pixels of the display panel, of calculating respective resonance-efficiencies of the pixel groups based on respective distances between a power unit and the pixel groups, and forming the pixels of the display panel according to the respective resonance-efficiencies of the pixel groups.

In example embodiments, the pixels coupled to one scan-line constitute one pixel group.

In example embodiments, the pixels coupled to each K scan-lines, where K is an integer greater than or equal to 2 and less than or equal to the number of all scan-lines, constitute one pixel group.

In example embodiments, the respective resonance-efficiencies of the pixel groups increase as the respective distances between the power unit and the pixel groups increase, and the respective resonance-efficiencies of the pixel groups decrease as the respective distances between the power unit and the pixel groups decrease.

In example embodiments, an etching area of respective buffer layers of the pixels decrease as the respective distances between the power unit and the pixel groups increase, and the etching area of the respective buffer layers of the pixels increases as the respective distances between the power unit and the pixel groups decrease.

In example embodiments, the respective buffer layers of the pixels are differently etched using stripe patterns.

In example embodiments, the respective buffer layers of the pixels are differently etched using grid patterns.

In example embodiments, the respective buffer layers of the pixels are differently etched using polygon patterns.

According to some example embodiments, a display panel, comprising: a plurality of scan-lines configured to transfer a scan signal, the scan-lines being arranged in a first direction, a plurality of data-lines configured to transfer a data signal, the data-lines being arranged in a second direction, a plurality of power-lines configured to transfer a high power voltage and a low power voltage, the power-lines being arranged in the first direction or the second direction, and a plurality of pixels formed at locations corresponding to crossing points of the scan-lines and the data-lines, the pixels being grouped into a plurality of pixel groups, the pixel groups have different respective resonance-efficiencies based on respective distances between a power unit and the pixel groups, the power unit being coupled to the power-lines.

In example embodiments, the pixels coupled to one scan-line constitute one pixel group.

In example embodiments, the pixels coupled to each K scan-lines, where K is an integer greater than or equal to 2 and less than or equal to the number of all scan-lines, constitute one pixel group.

In example embodiments, the respective resonance-efficiencies of the pixel groups increase as the respective distances between the power unit and the pixel groups increase, and the respective resonance-efficiencies of the pixel groups decrease as the respective distances between the power unit and the pixel groups decrease.

In example embodiments, an etching area of respective buffer layers of the pixels decrease as the respective distances between the power unit and the pixel groups increase, and the etching area of the respective buffer layers of the pixels increases as the respective distances between the power unit and the pixel groups decrease.

According to some example embodiments, an organic light emitting diode (OLED) display device comprises: a display panel having a plurality of pixels, the pixels being grouped into a plurality of pixel groups, a scan driving unit configured to provide a scan signal to the pixels, a data driving unit configured to provide a data signal to the pixels, a power unit configured to provide a high power voltage and a low power voltage to the pixels, and a timing control unit configured to control the scan driving unit, the data driving unit, and the power unit, the pixel groups may have different respective resonance-efficiencies based on respective distances between the power unit and the pixel groups.

In example embodiments, the pixels coupled to one scan-line constitute one pixel group.

In example embodiments, the pixels coupled to each K scan-lines, where K is an integer greater than or equal to 2 and less than or equal to the number of all scan-lines, constitute one pixel group.

In example embodiments, the respective resonance-efficiencies of the pixel groups increase as the respective distances between the power unit and the pixel groups increase, and the respective resonance-efficiencies of the pixel groups decrease as the respective distances between the power unit and the pixel groups decrease.

In example embodiments, the respective resonance-efficiencies of the pixel groups may be relatively high in a middle display region of the display panel when the high power voltage is transferred from an upper display region and a lower display region of the display panel to the middle display region of the display panel.

In example embodiments, the respective resonance-efficiencies of the pixel groups be relatively high in a lower display region of the display panel when the high power voltage is transferred from an upper display region of the display panel to the lower display region of the display panel.

In example embodiments, the respective resonance-efficiencies of the pixel groups be relatively high in the upper display region of the display panel when the high power voltage is transferred from the lower display region of the display panel to the upper display region of the display panel.

In example embodiments, an etching area of respective buffer layers of the pixels decrease as the respective distances between the power unit and the pixel groups increase, and the etching area of the respective buffer layers of the pixels increases as the respective distances between the power unit and the pixel groups decrease.

Therefore, a display panel according to example embodiments improve luminance uniformity by increasing respective resonance-efficiencies of pixels that are far from a power unit, and by decreasing respective resonance-efficiencies of pixels that are near to the power unit.

In addition, an organic light emitting display device having the display panel according to example embodiments may display a high-quality image.

Furthermore, a method of manufacturing a display panel according to example embodiments may manufacture a display panel having improved luminance uniformity by increasing respective resonance-efficiencies of pixels that are far from a power unit, and by decreasing respective resonance-efficiencies of pixels that are near to the power unit.

### BRIEF DESCRIPTION OF THE DRAWINGS

Illustrative, non-limiting example embodiments will be more clearly understood from the following detailed description taken in conjunction with the accompanying drawings.

FIG. 1 is a flowchart illustrating a method of manufacturing a display panel according to example embodiments.

FIG. 2 is a diagram illustrating an example of a display panel manufactured by a method of FIG. 1.

FIG. 3 is a diagram illustrating another example of a display panel manufactured by a method of FIG. 1.

FIG. 4 is a graph illustrating the reason why luminance uniformity of a display panel is improved by a method of FIG. 1.

FIG. 5 is a flowchart illustrating an example in which a resonance-structure is formed in pixels by a method of FIG. 1.

FIG. 6 is a diagram illustrating an example in which a resonance-structure having stripe patterns is formed in pixels by a method of FIG. 1.

FIG. 7 is a diagram illustrating an example in which a resonance-structure having grid patterns is formed in pixels by a method of FIG. 1.

FIG. 8 is a diagram illustrating an example in which a resonance-structure having polygon patterns is formed in pixels by a method of FIG. 1.

FIG. 9 is a graph illustrating resonance-efficiencies having a linear-shape in a display panel manufactured by a method of FIG. 1.

FIG. 10 is a graph illustrating resonance-efficiencies having a step-shape in a display panel manufactured by a method of FIG. 1.

FIG. 11 is a block diagram illustrating an organic light emitting display device according to example embodiments.

FIG. 12 is a block diagram illustrating an electronic device having an organic light emitting display device of FIG. 11.

### DETAILED DESCRIPTION OF CERTAIN INVENTIVE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

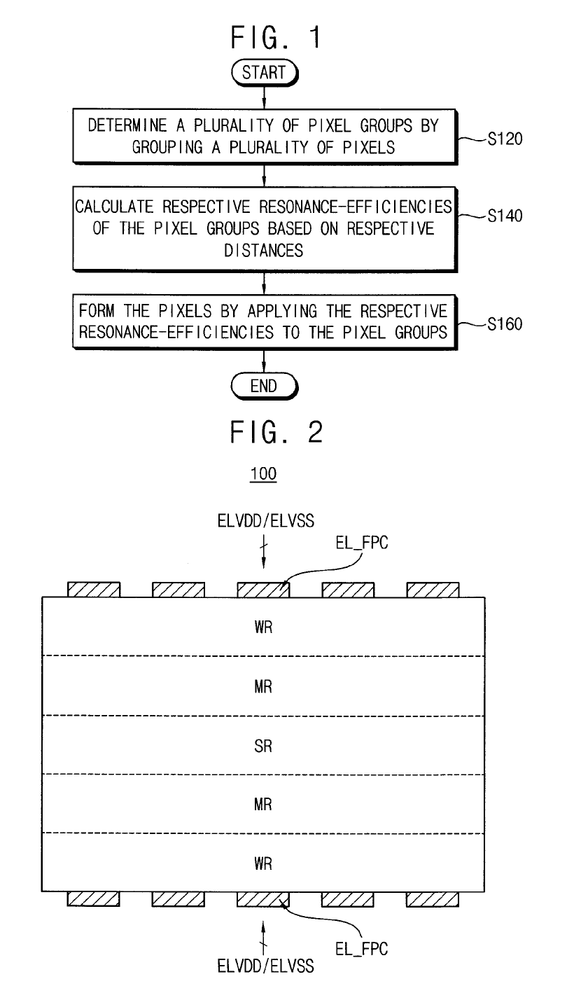

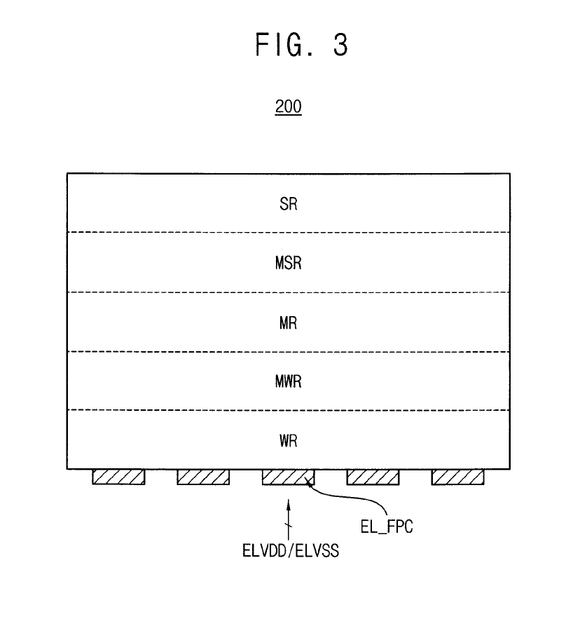

FIG. 1 is a flowchart illustrating a method of manufacturing a display panel according to various embodiments. FIG. 2 is a conceptual diagram illustrating an example of a display panel manufactured by the method of FIG. 1. FIG. 3 is a conceptual diagram illustrating another example of a display panel manufactured by the method of FIG. 1.

Referring to FIGS. 1 through 3, the method of FIG. 1 determines a plurality of pixel groups by grouping a plurality of pixels to be formed in the display panel 100 and 200 (Step S120), calculates respective resonance-efficiencies of the pixel groups based on respective distances between a power unit and the pixel groups (Step S140), and forms the pixels in the display panel 100 and 200 by applying the respective resonance-efficiencies to the pixel groups (Step S160).

Generally, a high power voltage ELVDD is transferred from the power unit to the pixels via power-lines. Here, a voltage drop (e.g., IR-DROP) of the high power voltage ELVDD occurs because the high power voltage ELVDD is transferred via the power-lines over a distance. Thus, the high power voltage ELVDD signal having a relatively low voltage level is applied to pixels that are far from the power unit, whereas the high power voltage ELVDD signal having a relatively high voltage level is applied to pixels that are near to the power unit. Since the driving transistor included in each pixel operates as a constant-current source or a constant-voltage source in an OLED display, the voltage drop of the high power voltage ELVDD results in a luminance decrease. That is, even when the same data signal is applied to each pixel, luminance of a display region (i.e., one group of pixels) that is far from the power unit may be lower than the luminance of a display region (i.e., another group of pixels) that is near to the power unit. For example, when the high power voltage ELVDD signal is transferred from a lower display region of the display panel (e.g., the display panel 200) to an upper display region of the display panel, the voltage drop of the high power voltage ELVDD signal will occur more frequently in the upper display region of the display panel. As a result, luminance of the upper display region of the display panel can greatly decrease because a current flowing through the OLED (i.e., referred to as an emission current) is reduced. On the other hand, when the high power voltage ELVDD signal is transferred from an upper display region of the display panel to a lower display region of the display panel, the voltage drop of the high power voltage ELVDD signal will occur more frequently in the lower display region of the display panel. As a result, luminance of the lower display region of the display panel can greatly decrease because the emission current is reduced. Furthermore, when the high power voltage ELVDD signal is transferred from an upper display region and a lower display region of the display panel (e.g., the display panel 100) to a middle display region of the display panel, the voltage drop of the high power voltage ELVDD signal can occur more frequently in the middle display region of the display panel. As a result, luminance of the middle display region of the display panel can greatly decrease because the emission current is reduced. Thus, in general, luminance uniformity of the display panel can be degraded due to the voltage drop of the high power voltage ELVDD signal. Moreover, the voltage drop of the high power voltage ELVDD signal becomes greater as the display panel gets wider. To overcome this problem, the method of FIG. 1 can improve luminance uniformity of the display panel by applying different respective resonance-efficiencies to the pixels (or to the pixel groups) of the display panel based on the respective distances between the power unit and the pixels (or the pixel groups). Hereinafter, the method of FIG. 1 will be described more specifically below.

The method of FIG. 1 determines the pixel groups by grouping the pixels to be formed in the display panel 100 and 200 (Step S120). As illustrated in FIG. 2, the power voltages ELVDD and ELVSS are transferred from the upper display region and the lower display region of the display panel 100 to the middle display region of the display panel 100 (i.e., both directions). As illustrated in FIG. 3, the power voltages ELVDD and ELVSS are transferred from the lower display region (or the upper display region) of the display panel 200 to the upper display region (or the lower display region) of the display panel 200 (i.e., one direction). In some embodiments, the power-lines by which the power voltages ELVDD and ELVSS are transferred are parallel with a plurality of data-lines in the display panel 100 and 200, and are perpendicular to a plurality of scan-lines in the display panel 100 and 200. Hence, the method of FIG. 1 can determine the pixel groups by at least one scan-line when the pixels are grouped into the pixel groups. In one example embodiment, the method of FIG. 1 defines pixels coupled to one scan-line into one pixel group. For example, when a full high definition (FHD) resolution (i.e., 1920×1080) is implemented by the display panel 100 and 200, 1080 pixel groups will exist in the display panel 100 and 200 because pixels coupled to each scan-line constitute their own respective pixel group. In this case, since the pixels are formed to have different respective resonance-efficiencies by each scan-line, the display panel 100 and 200 will have linear resonance-efficiencies. In another example embodiment, the method of FIG. 1 will set pixels coupled to K scan-lines, where K is an integer greater than or equal to 2 and less than or equal to the number of all scan-lines, to constitute one pixel group. For example, when a FHD resolution (i.e., 1920×1080) is implemented for the display panel 100 and 200, 108 pixel groups may exist in the display panel 100 and 200 if pixels coupled to K=10 scan-lines constitute one pixel group. In this case, since the pixels are formed to have different respective resonance-efficiencies by 10 scan-lines, the display panel 100 and 200 will have the resonance-efficiencies having a step-shape. For convenience of description, FIGS. 2 and 3 show that the display panel 100 and 200 has pixel groups with differences of resonance-efficiencies being defined by a stairstep-shape.

Next, the method of FIG. 1 calculates the respective resonance-efficiencies of the pixel groups based on the respective distances between the power unit and the pixel groups (Step S140). Here, a resonance-efficiency indicates a resonance effect due to a resonance structure related to an etching area of a buffer layer of each pixel included in an organic light emitting display device. As described above, the voltage drop of the high power voltage ELVDD will increase as a distance between the power unit and one pixel group increases. In addition, as the voltage drop of the high power voltage ELVDD increases, the emission current decreases, so that luminance of the pixels (or the pixel group) will decrease. Thus, the method of FIG. 1 increases the respective resonance-efficiencies of pixel groups that are far from the power unit, and decreases the respective resonance-efficiencies of the pixel groups that are near to the power unit.

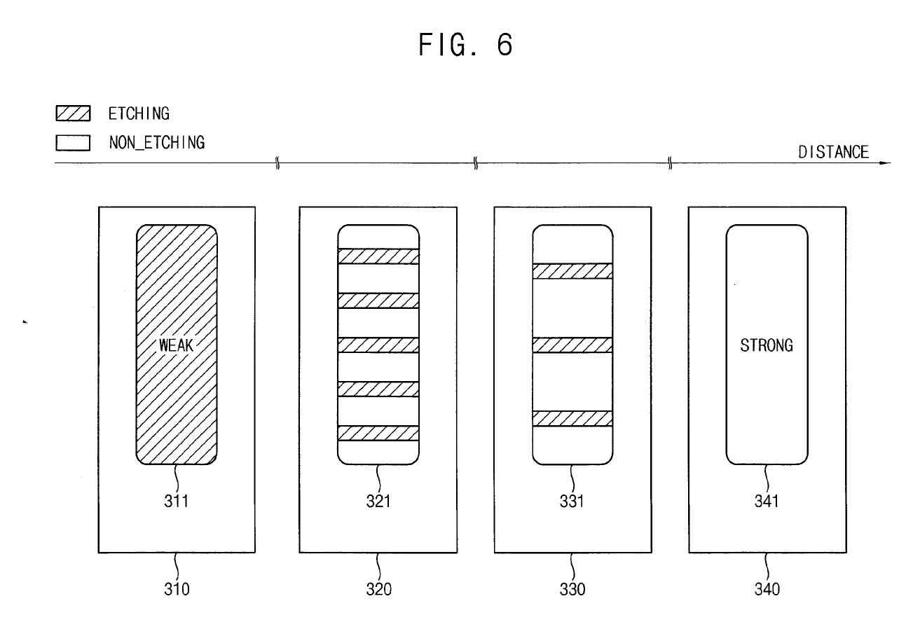

For the operation of forming pixels (S160), in some embodiments, the method of FIG. 1 will decrease the etching area of respective buffer layers of pixels when a pixel group including the pixels is far from the power unit, and will increase the etching area of respective buffer layers of pixels when a pixel group including the pixels is near to the power unit. In other words, the method of FIG. 1 will decrease the etching area of respective buffer layers of pixels as a distance between the power unit and a pixel group including the pixels increases, and will increase the etching area of respective buffer layers of pixels as a distance between the power unit and a pixel group including the pixels decreases. To this end, embodiments of the method of FIG. 1 may differently etch respective buffer layers of the pixels using specific patterns such as stripe patterns, grid patterns, polygon patterns, etc. The etching operation will be described more specifically with reference to FIGS. 5 through 8. As described above, when the method of FIG. 1 sets pixels coupled to one scan-line to constitute one pixel group, the display panel 100 and 200 will generally have pixel groups with different resonance-efficiencies forming a linear-shape. On the other hand, when the method of FIG. 1 sets pixels coupled to K scan-lines to constitute one pixel group, the display panel 100 and 200 will generally have pixel groups with different resonance-efficiencies forming a stairstep-shape.

After the respective resonance-efficiencies of the pixel groups are calculated based on the respective distances between the power unit and the pixel groups, the method of FIG. 1 forms the pixels in the display panel 100 and 200 by applying the respective resonance-efficiencies to the pixel groups (Step S160). FIG. 2 shows that the power voltages ELVDD and ELVSS are input to the display panel 100 via a flexible printed circuit board EL_FPC, etc. As illustrated in FIG. 2, the power voltages ELVDD and ELVSS are transferred from the upper display region and the lower display region of the display panel 100 to the middle display region of the display panel 100. In this case, the voltage drop of the high power voltage ELVDD may greatly increase in the middle display region of the display panel 100, and thus, the emission current will decrease in the pixels of the middle display region of the display panel 100 (i.e., luminance may decrease). Thus, the method of FIG. 1 can increase the respective resonance-efficiencies of the pixel groups in the middle display region of the display panel 100. It is assumed in FIG. 2 that pixels coupled to K scan-lines constitute one pixel group, and thus 3 pixel groups WR, MR, and SR exist. Specifically, the display panel 100 may include a first pixel group WR having a relatively low resonance-efficiency, a second pixel group MR having a relatively middle resonance-efficiency, and a third pixel group SR having a relatively high resonance-efficiency. FIG. 3 shows that the power voltages ELVDD and ELVSS are applied to the display panel 200 via a flexible printed circuit board EL_FPC, etc. As illustrated in FIG. 3, the power voltages ELVDD and ELVSS may be transferred from the lower display region of the display panel 200 to the upper display region of the display panel 200. In this case, the voltage drop of the high power voltage ELVDD can increase to a greater degree in the upper display region of the display panel 200, and thus, the emission current will decrease in the pixels of the upper display region of the display panel 200 (i.e., luminance may decrease). Thus, the method of FIG. 1 will increase the respective resonance-efficiencies of the pixel groups in the upper display region of the display panel 200. It is assumed in FIG. 3 that pixels coupled to K scan-lines constitute one pixel group, and 5 pixel groups WR, MWR, MR, MSR, and SR exist. Specifically, the display panel 200 may include a first pixel group WR having a relatively low resonance-efficiency, a second pixel group MWR having a relatively low-middle resonance-efficiency, a third pixel group MR having a relatively middle resonance-efficiency, a fourth pixel group MSR having a relatively high-middle resonance-efficiency, and a fifth pixel group SR having a relatively high resonance-efficiency.

In conclusion, the method of FIG. 1 can be used to manufacture a display panel having improved luminance uniformity by increasing the respective resonance-efficiencies of the pixel groups as the respective distances between the power unit and the pixel groups increase, and by decreasing the respective resonance-efficiencies of the pixel groups as the respective distances between the power unit and the pixel groups decrease. As a result, the display panel can achieve high luminance uniformity because a decrease of the emission current due to the voltage drop of the high power voltage ELVDD is compensated by different respective resonance-efficiencies of the pixels when the voltage drop of the high power voltage ELVDD occurs according to locations of the pixels on the display panel. Hence, an OLED display having such a display panel should display a higher-quality image. In particular, the method of FIG. 1 is a simple and low cost manufacturing process because it merely controls respective resonance-efficiencies of pixels by decreasing the etching area of respective buffer layers of pixels that are far from the power unit (i.e., the pixels are formed to have a strong resonance-structure), and by increasing the etching area of respective buffer layers of pixels that are near to the power unit (i.e., the pixels are formed to have a weak resonance-structure). That is, the method of FIG. 1 may decrease an etching area of respective buffer layers of pixels as respective distances between the power unit and a pixel group including the pixels increase, and may increase an etching area of respective buffer layers of pixels increases as respective distances between the power unit and a pixel group including the pixels decrease.

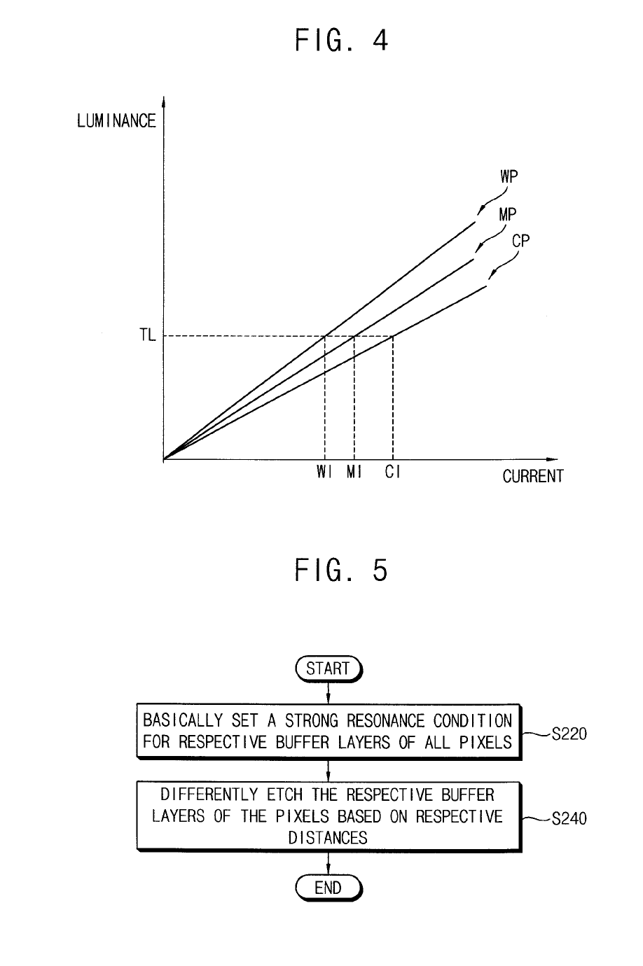

FIG. 4 is a graph illustrating the reason why luminance uniformity of a display panel can be improved by using the manufacturing method of FIG. 1.

Referring to FIG. 4, a first line CP indicates emission current-luminance characteristics of pixels that are formed to have a relatively low resonance-efficiency, a second line MP indicates emission current-luminance characteristics of pixels that are formed to have a relatively middle resonance-efficiency, and a third line WP indicates emission current-luminance characteristics of pixels that are formed to have a relatively high resonance-efficiency.

As described above, the voltage drop of the high power voltage ELVDD applied to pixels may increase as respective distances between a power unit and a pixel group including the pixels increase. As a result, luminance of the OLED may decrease because a current flowing through the OLED (i.e., the emission current) decreases. Thus, the method of FIG. 1 will increase respective resonance-efficiencies of pixel groups when the pixel groups are far from the power unit, and will decrease respective resonance-efficiencies of pixel groups when the pixel groups are near to the power unit. That is, the first line CP corresponds to the emission current-luminance characteristics of pixels included in a pixel group having a relatively short distance from the power unit, the second line MP corresponds to the emission current-luminance characteristics of pixels included in a pixel group having a relatively middle distance from the power unit, and the third line WP corresponds to the emission current-luminance characteristics of pixels included in a pixel group having a relatively long distance from the power unit. Specifically, a relatively large emission current CI will flow through respective OLEDs of the pixels included in the pixel group having a relatively short distance from the power unit because the voltage drop of the high power voltage ELVDD is relatively small. However, the pixels included in the pixel group having a relatively short distance from the power unit will achieve the target luminance TL because the pixels in the pixel group having a relatively short distance from the power unit have a relatively low resonance-efficiency. On the other hand, a relatively small emission current WI will flow through respective OLEDs of the pixels included in the pixel group having a relatively long distance from the power unit because the voltage drop of the high power voltage ELVDD is relatively great. However, the pixels included in the pixel group having a relatively long distance from the power unit will achieve the target luminance TL because the pixels included in the pixel group having a relatively long distance from the power unit have a relatively high resonance-efficiency. In addition, a relatively middle emission current MI will flow through respective OLEDs of the pixels included in the pixel group having a relatively middle distance from the power unit. Here, the pixels included in the pixel group having a relatively middle distance from the power unit will also achieve the target luminance TL. In conclusion, the method of FIG. 1 can efficiently compensate a decrease of the emission current due to the voltage drop of the high power voltage ELVDD by increasing respective resonance-efficiencies of pixel groups as respective distances between the power unit and the pixel groups increase, and by decreasing respective resonance-efficiencies of pixel groups as respective distances between the power unit and the pixel groups decrease. As a result, embodiments of the method of FIG. 1 manufacture a display panel having improved luminance uniformity.

FIG. 5 is a flowchart illustrating an example in which a resonance-structure is formed in pixels by the method of FIG. 1.

Referring to FIG. 5, the method of FIG. 1 can basically set a strong resonance condition for respective buffer layers of all pixels (Step S220), and then can differently etch the respective buffer layers of the pixels based on respective distances between the power unit and the pixels (Step S240). As a result, respective resonance-efficiencies of the pixels may differ because an etching area of the respective buffer layers of the pixels differ based on respective distances between the power unit and the pixels. Here, it should be understood that an etching area of respective buffer layers of the pixels indicates an etching area of respective buffer layers related to opening regions of the pixels (i.e., related to emission regions of the pixels).

Specifically, the method of FIG. 1 can basically set the strong resonance condition for the respective buffer layers of all pixels (Step S220). Here, a buffer layer indicates a layer that is formed on a substrate before transistors are formed. Hence, a resonance-efficiency can be determined according to the thickness of the buffer layer. Therefore, in order to achieve a weak resonance condition for the buffer layer of one pixel, the manufacturing method of FIG. 1 performs an etching operation on (i.e., etching) the buffer layer of the pixel. As a result, the strong resonance condition may be applied to one pixel when an etching area of the buffer layer of the pixel is relatively small, and the weak resonance condition may be applied to one pixel when an etching area of the buffer layer of the pixel is relatively large. As described above, the method of FIG. 1 may increase respective resonance-efficiencies of pixel groups as respective distances between the power unit and the pixel groups increase, and may decrease respective resonance-efficiencies of pixel groups as respective distances between the power unit and the pixel groups decrease. Thus, the method of FIG. 1 may decrease an etching area of the respective buffer layers of the pixels included in a pixel group that is far from the power unit, and may increase an etching area of the respective buffer layers of the pixels included in a pixel group that is near to the power unit. Generally, respective wavelengths that cause a resonance in an opening region of one pixel may differ from each other according to light colors. Hence, the strong resonance condition for red color (R) pixels, the strong resonance condition for green color (G) pixels, and the strong resonance condition for blue color (B) pixels are different from each other. Therefore, although the same strong resonance condition is applied to the red color pixels, the green color pixels, and the blue color pixels, a thickness of respective buffer layers of the red color pixels, a thickness of respective buffer layers of the green color pixels, and a thickness of respective buffer layers of the blue color pixels may be different from each other.

Next, the method of FIG. 1 can differently etch the respective buffer layers of the pixels based on the respective distances between the power unit and the pixels (Step S240). That is, the method of FIG. 1 may differently adjust an area ratio of a strong resonance area and a weak resonance area for each pixel group. In one example embodiment, the method of FIG. 1 may differently etch the respective buffer layers of the pixels using stripe patterns. In another example embodiment, the method of FIG. 1 may differently etch the respective buffer layers of the pixels using grid patterns. In still another example embodiment, the method of FIG. 1 may differently etch the respective buffer layers of the pixels using polygon patterns. For this operation, the method of FIG. 1 may form a buffer layer on a substrate, may spread a photo-resist layer on the buffer layer, may perform a light exposure on the photo-resist layer using a photo-mask that has specific patterns such as the stripe patterns, the grid patterns, the polygon patterns, etc., and then may etch the buffer layer. Since this process is exemplary, the present inventive concept is not limited thereto. In conclusion, the method of FIG. 1 may differently determine the respective resonance-efficiencies of the pixels by decreasing an etching area of the respective buffer layers of the pixels included in a pixel group that is far from the power unit, and by increasing an etching area of the respective buffer layers of the pixels included in a pixel group that is near to the power unit.

FIG. 6 is a diagram illustrating an example in which a resonance-structure having stripe patterns is formed in pixels by a method of FIG. 1.

Referring to FIG. 6, the method of FIG. 1 may differently etch respective buffer layers of opening regions 311, 321, 331, and 341 of pixels 310, 320, 330, and 340 included in a display panel based on respective distances between a power unit and the pixels 310, 320, 330, and 340. As illustrated in FIG. 6, the method of FIG. 1 uses stripe patterns to differently etch the respective buffer layers of the opening regions 311, 321, 331, and 341 of the pixels 310, 320, 330, and 340. Specifically, the method of FIG. 1 may increase respective resonance-efficiencies of pixel groups that are far from the power unit, and may decrease respective resonance-efficiencies of pixel groups that are near to the power unit. Thus, the method of FIG. 1 may decrease an etching area of the respective buffer layers of pixels included in a pixel group that is far from the power unit (i.e., a strong resonance condition), and may increase an etching area of the respective buffer layers of pixels included in a pixel group that is near to the power unit (i.e., a weak resonance condition). That is, in FIG. 6, the pixels 310, 320, 330, and 340 belong to different pixel groups, respectively. Here, at least one pixel that belongs to the same pixel group as the first pixel 310 may have the same etching area of the buffer layer as the first pixel 310, at least one pixel that belongs to the same pixel group as the second pixel 320 may have the same etching area of the buffer layer as the second pixel 320, at least one pixel that belongs to the same pixel group as the third pixel 330 may have the same etching area of the buffer layer as the third pixel 330, and at least one pixel that belongs to the same pixel group as the fourth pixel 340 may have the same etching area of the buffer layer as the fourth pixel 340. The pixel groups may be determined by at least one scan-line when the pixels 310, 320, 330, and 340 are grouped into the pixel groups. In one example embodiment, each pixel group may have one scan-line. In another example embodiment, each pixel group may have a plurality of scan-lines (e.g., 10 scan-lines, 20 scan-lines, 30 scan-lines, 40 scan-lines, etc.). Thus, the method of FIG. 1 may improve luminance uniformity of the display panel by compensating a decrease of an emission current due to a voltage drop of the high power voltage ELVDD by different respective resonance-efficiencies of the pixels 310, 320, 330, and 340 when the voltage drop of the high power voltage ELVDD occurs according to locations of the pixels 310, 320, 330, and 340 on the display panel. Here, it should be understood that an etching area of respective buffer layers of the pixels 310, 320, 330, and 340 indicates an etching area of respective buffer layers related to the opening regions 311, 321, 331, and 341 of the pixels 310, 320, 330, and 340 (i.e., related to emission regions 311, 321, 331, and 341 of the pixels 310, 320, 330, and 340).

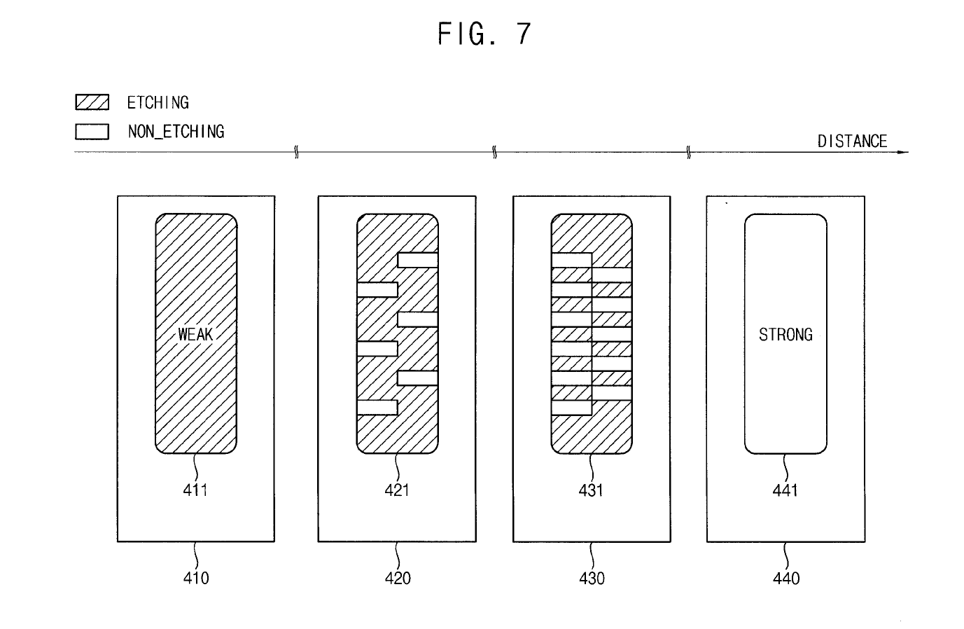

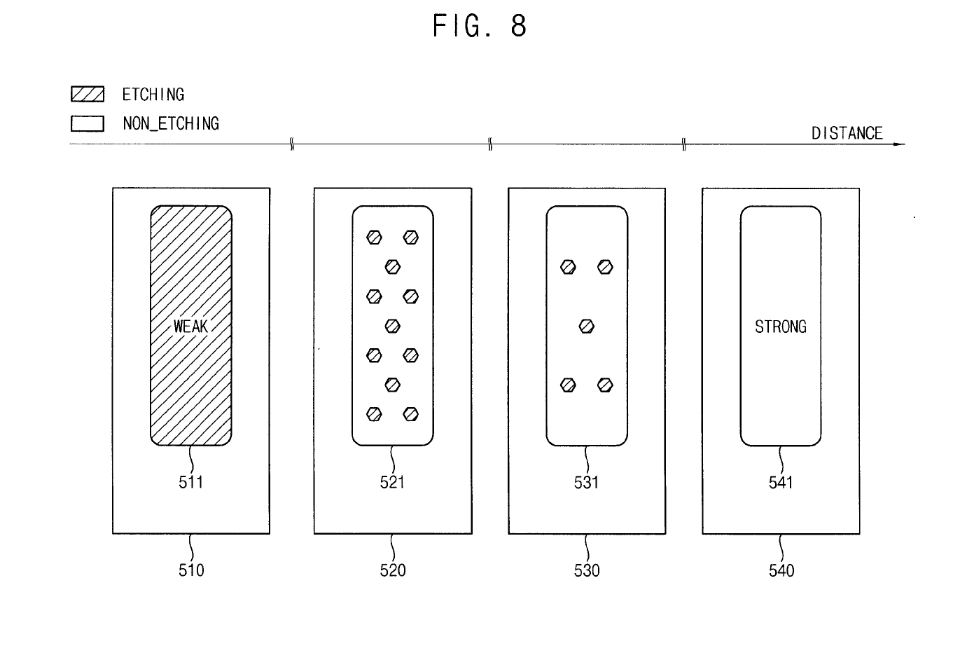

FIG. 7 is a diagram illustrating an example in which a resonance-structure having grid patterns is formed in pixels by a method of FIG. 1.

Referring to FIG. 7, the method of FIG. 1 may differently etch respective buffer layers of opening regions 411, 421, 431, and 441 of pixels 410, 420, 430, and 440 included in a display panel based on respective distances between a power unit and the pixels 410, 420, 430, and 440. As illustrated in FIG. 7, the method of FIG. 1 uses grid patterns to differently etch the respective buffer layers of the opening regions 411, 421, 431, and 441 of the pixels 410, 420, 430, and 440. Specifically, the method of FIG. 1 may increase respective resonance-efficiencies of pixel groups that are far from the power unit, and may decrease respective resonance-efficiencies of pixel groups that are near to the power unit. Thus, the method of FIG. 1 may decrease an etching area of the respective buffer layers of pixels included in a pixel group that is far from the power unit (i.e., a strong resonance condition), and may increase an etching area of the respective buffer layers of pixels included in a pixel group that is near to the power unit (i.e., a weak resonance condition). That is, in FIG. 7, the pixels 410, 420, 430, and 440 belong to different pixel groups, respectively. Here, at least one pixel that belongs to the same pixel group as the first pixel 410 may have the same etching area of the buffer layer as the first pixel 410, at least one pixel that belongs to the same pixel group as the second pixel 420 may have the same etching area of the buffer layer as the second pixel 420, at least one pixel that belongs to the same pixel group as the third pixel 430 may have the same etching area of the buffer layer as the third pixel 430, and at least one pixel that belongs to the same pixel group as the fourth pixel 440 may have the same etching area of the buffer layer as the fourth pixel 440. The pixel groups may be determined by at least one scan-line when the pixels 410, 420, 430, and 440 are grouped into the pixel groups. In one example embodiment, each pixel group may have one scan-line. In another example embodiment, each pixel group may have a plurality of scan-lines (e.g., 10 scan-lines, 20 scan-lines, 30 scan-lines, 40 scan-lines, etc.). Thus, the method of FIG. 1 may improve luminance uniformity of the display panel by compensating a decrease of an emission current due to a voltage drop of the high power voltage ELVDD by different respective resonance-efficiencies of the pixels 410, 420, 430, and 440 when the voltage drop of the high power voltage ELVDD occurs according to locations of the pixels 410, 420, 430, and 440 on the display panel. Here, it should be understood that an etching area of respective buffer layers of the pixels 410, 420, 430, and 440 indicates an etching area of respective buffer layers related to the opening regions 411, 421, 431, and 441 of the pixels 410, 420, 430, and 440 (i.e., related to emission regions 411, 421, 431, and 441 of the pixels 410, 420, 430, and 440).

FIG. 8 is a diagram illustrating an example in which a resonance-structure having polygon patterns is formed in pixels by a method of FIG. 1.

Referring to FIG. 8, the method of FIG. 1 may differently etch respective buffer layers of opening regions 511, 521, 531, and 541 of pixels 510, 520, 530, and 540 included in a display panel based on respective distances between a power unit and the pixels 510, 520, 530, and 540. As illustrated in FIG. 8, the method of FIG. 1 uses polygon patterns to differently etch the respective buffer layers of the opening regions 511, 521, 531, and 541 of the pixels 510, 520, 530, and 540. Specifically, the method of FIG. 1 may increase respective resonance-efficiencies of pixel groups that are far from the power unit, and may decrease respective resonance-efficiencies of pixel groups that are near to the power unit. Thus, the method of FIG. 1 may decrease an etching area of the respective buffer layers of pixels included in a pixel group that is far from the power unit (i.e., a strong resonance condition), and may increase an etching area of the respective buffer layers of pixels included in a pixel group that is near to the power unit (i.e., a weak resonance condition). That is, in FIG. 8, the pixels 510, 520, 530, and 540 belong to different pixel groups, respectively. Here, at least one pixel that belongs to the same pixel group as the first pixel 510 may have the same etching area of the buffer layer as the first pixel 510, at least one pixel that belongs to the same pixel group as the second pixel 520 may have the same etching area of the buffer layer as the second pixel 520, at least one pixel that belongs to the same pixel group as the third pixel 530 may have the same etching area of the buffer layer as the third pixel 530, and at least one pixel that belongs to the same pixel group as the fourth pixel 540 may have the same etching area of the buffer layer as the fourth pixel 540. The pixel groups may be determined by at least one scan-line when the pixels 510, 520, 530, and 540 are grouped into the pixel groups. In one example embodiment, each pixel group may have one scan-line. In another example embodiment, each pixel group may have a plurality of scan-lines (e.g., 10 scan-lines, 20 scan-lines, 30 scan-lines, 40 scan-lines, etc.). Thus, the method of FIG. 1 may improve luminance uniformity of the display panel by compensating a decrease of an emission current due to a voltage drop of the high power voltage ELVDD by different respective resonance-efficiencies of the pixels 510, 520, 530, and 540 when the voltage drop of the high power voltage ELVDD occurs according to locations of the pixels 510, 520, 530, and 540 on the display panel. Here, it should be understood that an etching area of respective buffer layers of the pixels 510, 520, 530, and 540 indicates an etching area of respective buffer layers related to the opening regions 511, 521, 531, and 541 of the pixels 510, 520, 530, and 540 (i.e., related to emission regions 511, 521, 531, and 541 of the pixels 510, 520, 530, and 540).

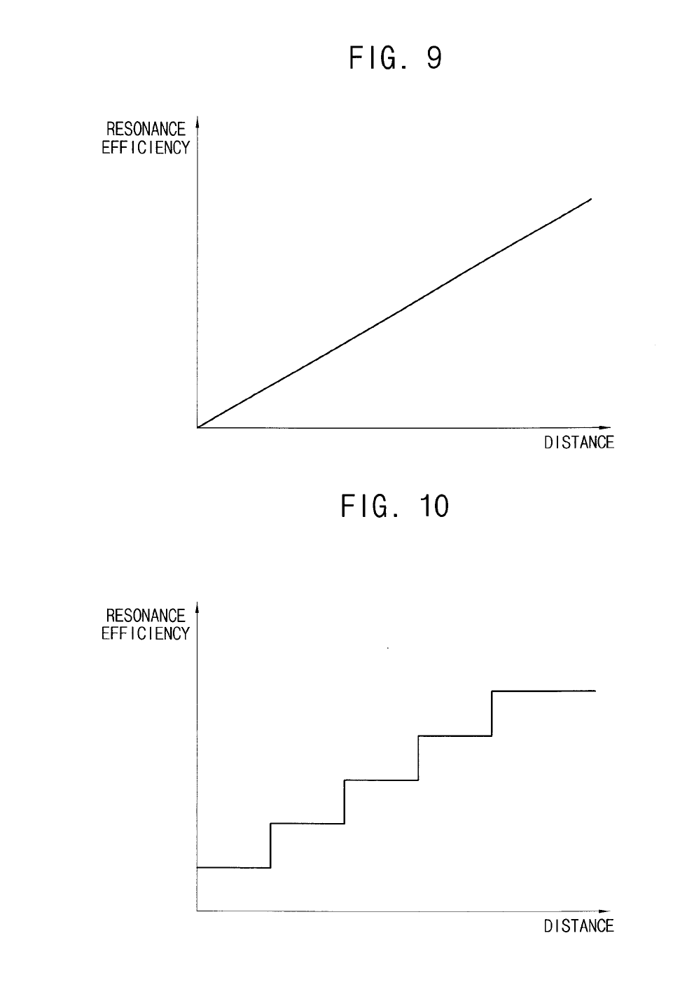

FIG. 9 is a graph illustrating resonance-efficiencies having a linear-shape in a display panel manufactured by a method of FIG. 1. FIG. 10 is a graph illustrating resonance-efficiencies having a stairstep-shape in a display panel manufactured by a method of FIG. 1.

Referring to FIGS. 9 and 10, it is illustrated that pixel groups of a display panel have different respective resonance-efficiencies based on respective distances between a power unit and the pixel groups. As described above, the method of FIG. 1 may increase respective resonance-efficiencies of the pixel groups that are far from the power unit, and may decrease respective resonance-efficiencies of pixel groups that are near to the power unit. Here, the method of FIG. 1 may determine the pixel groups by grouping a plurality of pixels to be formed in the display panel. In example embodiments, the method of FIG. 1 may determine the pixel groups by at least one scan-line when the pixels are grouped into the pixel groups.

In one example embodiment, the method of FIG. 1 may set a plurality of pixels coupled to one scan-line to constitute one pixel group. For example, when a FHD resolution (i.e., 1920×1080) is implemented for the display panel, 1080 pixel groups may exist in the display panel because pixels coupled to one scan-line constitute one pixel group. In this case, as illustrated in FIG. 9, the display panel may have resonance-efficiencies having a linear-shape because pixels are formed to have different respective resonance-efficiencies by each scan-line. In another example embodiment, the method of FIG. 1 may set a plurality of pixels coupled to K scan-lines, where K is an integer greater than or equal to 2 and less than or equal to the number of all scan-lines, to constitute one pixel group. For example, when a FHD resolution (i.e., 1920×1080) is implemented for the display panel, 108 pixel groups may exist in the display panel if pixels coupled to 10 scan-lines constitute one pixel group. In this case, since pixels are formed to have different respective resonance-efficiencies by 10 scan-lines, the display panel may have resonance-efficiencies having a step-shape. Meanwhile, as illustrated in FIG. 9, when pixels coupled to one scan-line constitute one pixel group, a decrease of an emission current due to a voltage drop of the high power voltage ELVDD may be accurately compensated by the different respective resonance-efficiencies. However, a process for etching respective buffer layers of the pixels may be relatively complicated. On the other hand, as illustrated in FIG. 10, when pixels coupled to K scan-lines constitute one pixel group, a process for etching respective buffer layers of the pixels may be relatively simplified. However, a decrease of an emission current due to a voltage drop of the high power voltage ELVDD may not be accurately compensated by the different respective resonance-efficiencies. Thus, the pixel groups need to be determined considering the above trade-off relation.

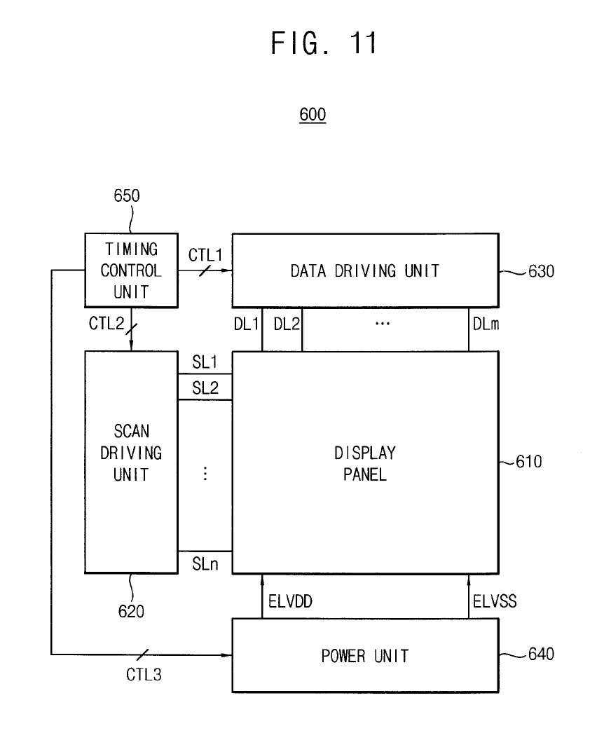

FIG. 11 is a block diagram illustrating an organic light emitting display device according to example embodiments.

Referring to FIG. 11, the organic light emitting display device 600 may include a display panel 610, a scan driving unit 620, a data driving unit 630, a power unit 640, and a timing control unit 650.

The display panel 610 may include a plurality of pixels. Specifically, the display panel 610 may further include a plurality of scan-lines SL1 through SLn arranged in a first direction (e.g., X-axis direction in FIG. 11), the scan-lines SL1 through SLn transferring a scan signal, a plurality of data-lines DL1 through DLm arranged in a second direction (e.g., Y-axis direction in FIG. 11), the data-lines DL1 through DLm transferring a data signal, and a plurality of power-lines arranged in the first direction or the second direction, the power-lines transferring a high power voltage ELVDD and a low power voltage ELVSS. Thus, the pixels may be arranged at locations corresponding to crossing points of the scan-lines SL1 through SLn and the data-lines DL1 through DLm. Here, the pixels may be grouped into a plurality of pixel groups. In addition, the pixel groups may have different respective resonance-efficiencies based on respective distances between the power unit 640 and the pixel groups. In one example embodiment, pixels coupled to one scan-line SL1 through SLn may constitute one pixel group. In another example embodiment, pixels coupled to K scan-lines SL1 through SLn, where K is an integer greater than or equal to 2 and less than or equal to the number of all scan-lines SL1 through SLn, may constitute one pixel group. As described above, respective resonance-efficiencies of the pixel groups that are far from the power unit 640 may be relatively high, and respective resonance-efficiencies of the pixel groups that are near to the power unit 640 may be relatively low. To this end, pixels included in a pixel group that is far from the power unit 640 may have a relatively small etching area of a buffer layer, and pixels included in a pixel group that is near to the power unit 640 may have a relatively large etching area of the buffer layer.

The scan driving unit 620 may provide the scan signal to the pixels via the scan-lines SL1 through SLn. The data driving unit 630 may provide the data signal to the pixels via the data-lines DL1 through DLm. The power unit 640 may generate the high power voltage ELVDD and the low power voltage ELVSS to provide the high power voltage ELVDD and the low power voltage ELVSS to the pixels via the power-lines. The timing control unit 650 may generate a plurality of control signals CTL1, CTL2, and CLT3 to provide the control signals CTL1, CTL2, and CLT3 to the scan driving unit 620, the data driving unit 630, and the power unit 640. That is, the timing control unit 650 may control the scan driving unit 620, the data driving unit 630, and the power unit 640. It is illustrated in FIG. 11 that the power unit 640 is located near a lower display region of the display panel 610. Thus, pixels included in the lower display region of the display panel 610 may have a relatively low resonance-efficiency, and pixels included in an upper display region of the display panel 610 may have a relatively high resonance-efficiency. On the other hand, the power unit 640 may be located near the upper display region of the display panel 610. Thus, the pixels included in the upper display region of the display panel 610 may have a relatively low resonance-efficiency, and the pixels included in the lower display region of the display panel 610 may have a relatively high resonance-efficiency. In some example embodiments, the high power voltage ELVDD and the low power voltage ELVSS may be transferred from the upper display region and the lower display region of the display panel 610 to a middle display region of the display panel 610. In this case, pixels included in the middle display region of the display panel 610 may have a relatively high resonance-efficiency.

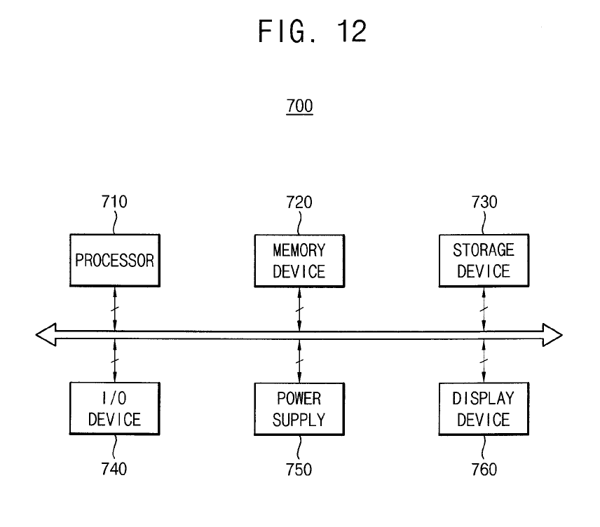

FIG. 12 is a block diagram illustrating an electronic device having an organic light emitting display device of FIG. 11.

Referring to FIG. 12, the electronic device 700 may include a processor 710, a memory device 720, a storage device 730, an input/output (I/O) device 740, a power supply 750, and an organic light emitting display device 760. Here, the organic light emitting display device 760 may correspond to the organic light emitting display device 600 of FIG. 11. In addition, the electronic device 700 may further include a plurality of ports for communicating a video card, a sound card, a memory card, a universal serial bus (USB) device, other electronic devices, etc.

The processor 710 may perform various computing functions. The processor 710 may be a micro processor, a central processing unit (CPU), etc. The processor 710 may be coupled to other components via an address bus, a control bus, a data bus, etc. Further, the processor 710 may be coupled to an extended bus such as a peripheral component interconnection (PCI) bus. The memory device 720 may store data for operations of the electronic device 700. For example, the memory device 720 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, etc., and/or at least one volatile memory device such as a dynamic random access memory (DRAM) device, a static random access memory (SRAM) device, a mobile DRAM device, etc. The storage device 730 may be a solid state drive (SSD) device, a hard disk drive (HDD) device, a CD-ROM device, etc.

The I/O device 740 may be an input device such as a keyboard, a keypad, a touchpad, a touch-screen, a mouse, etc., and an output device such as a printer, a speaker, etc. According to some example embodiments, the organic light emitting display device 760 may be included in the I/O device 740. The power supply 750 may provide a power for operations of the electronic device 700. The organic light emitting display device 760 may communicate with other components via the buses or other communication links. As described above, the organic light emitting display device 760 may include a display panel, a scan driving unit, a data driving unit, a power unit, and a timing control unit, etc. Here, the display panel may include a plurality of pixels. The pixels are grouped into a plurality of pixel groups. The pixel groups may have different respective resonance-efficiencies based on respective distances between the power unit and the pixel groups. As a result, the display panel may have improved luminance uniformity by compensating a decrease of an emission current due to a voltage drop of a high power voltage ELVDD by different respective resonance-efficiencies. Therefore, the organic light emitting display device 760 may display a high-quality image.

The present inventive concept may be applied to various products having an OLED display. For example, the present inventive concept may be applied to a computer monitor, a laptop, a digital camera, a cellular phone, a smartphone, a smart pad, a television, a personal digital assistant (PDA), a portable multimedia player (PMP), a MP3 player, a navigation system, a game console, a video phone, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a display panel of an organic light emitting diode (OLED) display, wherein the display panel has a plurality of pixels, the method comprising:
determining a plurality of pixel groups by grouping the pixels of the display panel;
calculating respective resonance-efficiencies of the pixel groups based on respective distances between a power unit and the pixel groups; and
forming the pixels of the display panel according to the respective resonance-efficiencies of the pixel groups.

2. The method of claim 1, wherein the pixels coupled to one scan-line constitute one pixel group.

3. The method of claim 1, wherein the pixels coupled to each K scan-lines, where K is an integer greater than or equal to 2 and less than or equal to the number of all scan-lines, constitute one pixel group.

4. The method of claim 1,
wherein the respective resonance-efficiencies of the pixel groups increase as the respective distances between the power unit and the pixel groups increase, and
wherein the respective resonance-efficiencies of the pixel groups decrease as the respective distances between the power unit and the pixel groups decrease.

5. The method of claim 4,
wherein an etching area of respective buffer layers of the pixels decreases as the respective distances between the power unit and the pixel groups increase, and
wherein the etching area of the respective buffer layers of the pixels increases as the respective distances between the power unit and the pixel groups decrease.

6. The method of claim 5, wherein the respective buffer layers of the pixels are differently etched using stripe patterns.

7. The method of claim 5, wherein the respective buffer layers of the pixels are differently etched using grid patterns.

8. The method of claim 5, wherein the respective buffer layers of the pixels are differently etched using polygon patterns.

9. A display panel, comprising:
a plurality of scan-lines configured to transfer a scan signal, the scan-lines being arranged in a first direction;
a plurality of data-lines configured to transfer a data signal, the data-lines being arranged in a second direction;
a plurality of power-lines configured to transfer a high power voltage and a low power voltage, the power-lines being arranged in the first direction or the second direction; and
a plurality of pixels formed at locations corresponding to crossing points of the scan-lines and the data-lines, the pixels being grouped into a plurality of pixel groups,
wherein the pixel groups have different respective resonance-efficiencies based on respective distances between a power unit and the pixel groups, the power unit being coupled to the power-lines.

10. The display panel of claim 9, wherein the pixels coupled to one scan-line constitute one pixel group.

11. The display panel of claim 9, wherein the pixels coupled to each K scan-lines, where K is an integer greater than or equal to 2 and less than or equal to the number of all scan-lines, constitute one pixel group.

12. The display panel of claim 9,
wherein the respective resonance-efficiencies of the pixel groups increase as the respective distances between the power unit and the pixel groups increase, and
wherein the respective resonance-efficiencies of the pixel groups decrease as the respective distances between the power unit and the pixel groups decrease.

13. The display panel of claim 12,
wherein an etching area of respective buffer layers of the pixels decreases as the respective distances between the power unit and the pixel groups increase, and
wherein the etching area of the respective buffer layers of the pixels increases as the respective distances between the power unit and the pixel groups decrease.

14. An organic light emitting diode (OLED) display device, comprising:
a display panel having a plurality of pixels, the pixels being grouped into a plurality of pixel groups;
a scan driving unit configured to provide a scan signal to the pixels;
a data driving unit configured to provide a data signal to the pixels;
a power unit configured to provide a high power voltage and a low power voltage to the pixels; and
a timing control unit configured to control the scan driving unit, the data driving unit, and the power unit,
wherein the pixel groups have different respective resonance-efficiencies based on respective distances between the power unit and the pixel groups.

15. The device of claim 14, wherein the pixels coupled to one scan-line constitute one pixel group.

16. The device of claim 14, wherein the pixels coupled to each K scan-lines, where K is an integer greater than or equal to 2 and less than or equal to the number of all scan-lines, constitute one pixel group.

17. The device of claim 14,
wherein the respective resonance-efficiencies of the pixel groups increase as the respective distances between the power unit and the pixel groups increase, and
wherein the respective resonance-efficiencies of the pixel groups decrease as the respective distances between the power unit and the pixel groups decrease.

18. The device of claim 17, wherein the respective resonance-efficiencies of the pixel groups are relatively high in a middle display region of the display panel when the high power voltage is transferred from an upper display region and a lower display region of the display panel to the middle display region of the display panel.

19. The device of claim 17,
wherein the respective resonance-efficiencies of the pixel groups are relatively high in a lower display region of the display panel when the high power voltage is transferred from an upper display region of the display panel to the lower display region of the display panel, and
wherein the respective resonance-efficiencies of the pixel groups are relatively high in the upper display region of the display panel when the high power voltage is transferred from the lower display region of the display panel to the upper display region of the display panel.

20. The device of claim 17,
wherein an etching area of respective buffer layers of the pixels decreases as the respective distances between the power unit and the pixel groups increase, and
wherein the etching area of the respective buffer layers of the pixels increases as the respective distances between the power unit and the pixel groups decrease.
